(19) United States
(12) Patent Application Publication
(10) Pub. No.: US 2020/0251934 A1
(43) Pub. Date: Aug. 6, 2020

(54) RADIO-FREQUENCY/MICROWAVE ENERGY HARVESTING DEVICE BASED ON SPINTRONICS

(71) Applicant: SUZHOU INSTITUTE OF NANO-TECH AND NANO-BIONICS(SINANO), CHINESE ACADEMY OF SCIENCES, Suzhou, Jiangsu (CN)

(72) Inventors: Zhongming ZENG, Suzhou (CN); Giovanni FINOCCHIO, Suzhou (CN); Bin FANG, Suzhou (CN); Jialin CAI, Suzhou (CN); Wei TANG, Suzhou (CN); Xin LUO, Suzhou (CN); Rongxin XIONG, Suzhou (CN); Baoshun ZHANG, Suzhou (CN)

(73) Assignee: SUZHOU INSTITUTE OF NANO-TECH AND NANO-BIONICS(SINANO) CHINESE ACADEMY OF SCIENCES, Suzhou, Jiangsu (CN)

(21) Appl. No.: 16/474,063

(22) PCT Filed: Mar. 24, 2017
(86) PCT No.: PCT/CN2017/078000

§ 371 Date: Jun. 26, 2019

(30) Foreign Application Priority Data
Dec. 27, 2016 (CN) 201611227721.1

(51) Int. Cl. H02J 50/20; H02J 50/00

(52) U.S. Cl. CPC H02J 50/20; H02J 50/001

(57) ABSTRACT

A new RF/microwave energy harvesting device based on spintronics is provided. The device comprises at least one RF/microwave energy conversion element comprising a first magnetic layer connected to a RF/microwave signal receiving element; a non-magnetic space layer; and an energy conversion layer accumulating positive and negative charges at both of upper and lower ends of the RF/microwave energy conversion element to implement a conversion of a RF/microwave energy into a direct voltage signal. Compared with the prior art, the device has advantages such as a simple structure, a small size, a wide operating frequency and the like.

### TECHNICAL FIELD

The present disclosure relates to a radio-frequency (RF)/microwave energy harvesting technology, especially to a new RF/microwave energy harvesting device based on spintronics.

### BACKGROUND ART

With rapid developments of a large-scale integrated circuit manufacturing technology and a hyperfine processing technology, a micro wireless sensor and a Micro-Electro-Mechanical system (MEMS) have been or will be widely applied to many fields, such as industry, agriculture, military, aeronautics and astronautics, medicine, environmental monitoring, family service and the like. At present, the wireless sensor and MEMS are powered by batteries or cables. However, in some applications, such as scattered wireless sensors mounted in the wild, it is impractical to supply power by batteries or cables. Especially, when the wireless sensors are powered by batteries, it is quite difficult to periodically replace a large number of batteries. Thus, energy supply is an important problem of the wireless sensor and MEMS to be solved.

Wireless charging is expected to solve the problem of energy supply for such applications. In the ambient condition, there are several kinds of electromagnetic wave energies, such as communication microwave energy, television signals, WiFi, etc. How to harvest and utilize those energies (namely, radio-frequency energy and microwave energy) to supply power for the wireless sensors and portable electronics has become an emerging issue. The current mainstream wireless energy harvesting technologies are based on electromagnetic induction or semiconductor diode, wherein the former has high conversion efficiency, but has limitations, such as short transmission distance and large size; and the latter has problems such as a small power capacity, a diode being easily broken down, high harmonics being generated and the like. Meanwhile, the above technologies are confronted with a narrow operating frequency and a size that is difficult to meet the miniaturization requirements.

### SUMMARY

In order to overcome defects in the prior art, the present disclosure aims to provide a new radio-frequency (RF)/microwave energy harvesting device based on spintronics, thereby providing a power generation device having a simple structure and capable of harvesting the RF/microwave energy and converting the RF/microwave energy into DC electric energy.

According to the present disclosure, a new RF/microwave energy harvesting device based on spintronics is provided. The device comprises at least one RF/microwave energy conversion element comprising a first magnetic layer connected to a RF/microwave signal receiving element; a non-magnetic space layer; and another magnetic layer, namely, an energy conversion layer accumulating positive and negative charges at upper and lower ends of the RF/microwave energy conversion element to convert a RF/microwave energy into a direct voltage signal. Compared with the prior art, the device has advantages such as simple structure, small size, wide operating frequency, etc .

Further, the space layer is provided on the first magnetic layer, and the energy conversion layer is provided on the space layer.

Further, the first magnetic layer comprises: an anti-ferromagnetic layer; at least two second magnetic layers provided on the anti-ferromagnetic layer; and a metal layer provided between two adjacent ones of the second magnetic layers.

Further, the first magnetic layer includes at least two first magnetic layers, the energy conversion layer is provided between two adjacent ones of the first magnetic layers, and the space layer is provided between the first magnetic layers and the energy conversion layer.

Further, the energy conversion layer includes at least two energy conversion layers, and the space layer is provided between two adjacent ones of the energy conversion layers.

Further, the space layer is made of a metal or an insulating material.

Further, when the space layer is made of a metal material, the metal material is one of copper and silver; and when the space layer is made of an insulating material, the insulating material is one of magnesium oxide, aluminum oxide and the like.

Further, when the space layer is made of the metal material, the space layer has a thickness of 0.5 nm-5 nm; and when the space layer is made of the insulating material, the space layer has a thickness of 0.5 nm-3 nm.

Further, the energy conversion layer is made of a magnetic material which is at least one of NiFe, Fe, Co, FeB, CoFeB, Co/Pt, Co/Pd, Co/Ni, CoFeSiB and TeFeCoAl.

Further, the RF/microwave energy conversion element includes two or more RF/microwave energy conversion elements, and the RF/microwave energy conversion elements are connected to each other in series or in parallel.

Compared with the prior art, the new RF/microwave energy harvesting device based on spintronics according to the present disclosure has advantages such as simple structure, small size, wide operating frequency range and high energy conversion efficiency per unit area; and the new RF/microwave energy harvesting device based on spintronics according to the present disclosure is operated under a room temperature, has no requirement for the environment where electromagnetic energy will be harvested, and may be applied to various fields such as wireless charging, electromagnetic energy harvesting and the like.

### BRIEF DESCRIPTION OF THE DRAWINGS

FIG. 1 is a structure schematic diagram according to the present disclosure.

FIG. 2 is a structure schematic diagram of a first embodiment of a RF/microwave energy conversion element according to the present disclosure.

FIG. 3 is a structure schematic diagram of a second embodiment of a RF/microwave energy conversion element according to the present disclosure.

FIG. 4 is a structure schematic diagram of a third embodiment of a RF/microwave energy conversion element according to the present disclosure.

FIG. 5 is a structure schematic diagram of a fourth embodiment of a RF/microwave energy conversion element according to the present disclosure.

FIG. 6A is a structure schematic diagram of a fifth embodiment 5 of a RF/microwave energy conversion element according to the present disclosure.

FIG. 6B is a RF/microwave energy harvesting performance diagram of the fifth embodiment according to the present disclosure.

FIG. 7 is a structure schematic diagram of a sixth embodiment of a RF/microwave energy conversion element according to the present disclosure.

FIG. 8 is a structure schematic diagram of a seventh embodiment of a RF/microwave energy conversion element according to the present disclosure.

FIG. 9 is a structure schematic diagram of a eighth embodiment of a RF/microwave energy conversion element according to the present disclosure.

FIG. 10 is a structure schematic diagram of a ninth embodiment of a RF/microwave energy conversion element according to the present disclosure.

FIG. 11 is a structure schematic diagram of a tenth embodiment of a RF/microwave energy conversion element according to the present disclosure.

FIG. 12 is a structure schematic diagram of a eleventh embodiment of a RF/microwave energy conversion element according to the present disclosure.

FIG. 13 is a schematic diagram of a RF/microwave energy conversion element being connected in series in a nano power generation device according to the present disclosure.

FIG. 14 is a schematic diagram of a RF/microwave energy conversion element being connected in parallel in a nano power generation device according to the present disclosure.

### DETAILED DESCRIPTION OF EXEMPLARY EMBODIMENTS

Hereinafter, the present disclosure will be further described with reference to the figures and embodiments.

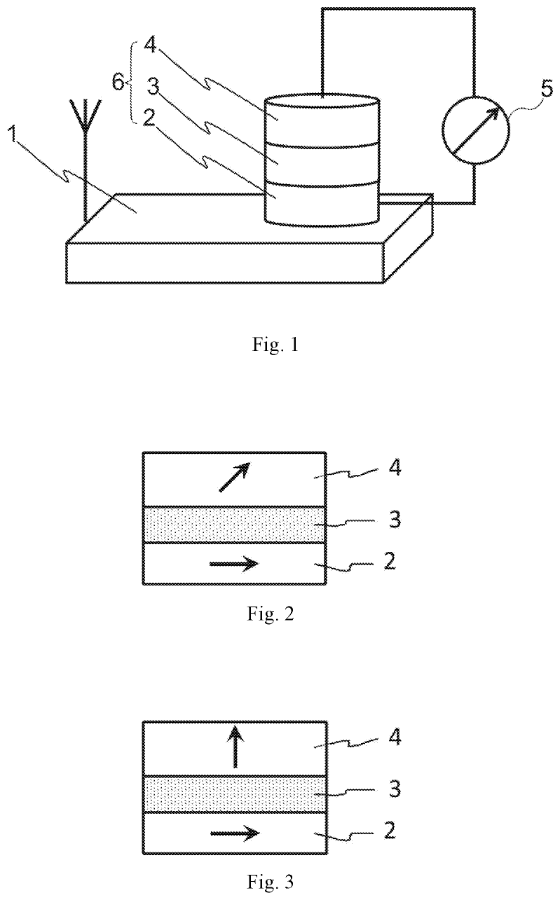

As shown in FIG. 1, a new RF/microwave energy harvesting device based on spintronics according to the present disclosure includes at least one RF/microwave energy conversion element 6 for converting RF/microwave energy into a direct voltage signal.

The RF/microwave energy conversion element 6 at least includes a first magnetic layer 2 which has a fixed in-plane magnetization axis, a non-magnetic space layer 3 and an energy conversion layer 4, wherein the first magnetic layer 2 is connected to a RF/microwave signal receiving element 1, and the energy conversion layer 4 accumulates positive and negative charges at both of upper and lower ends of the RF/microwave energy conversion element 6 to implement the conversion of a RF/microwave energy into a direct voltage signal.

Acquisition of a signal of the RF/microwave energy conversion element 6 may be implemented by the RF/microwave signal receiving element 1 connected thereto, the RF/microwave energy conversion element 6 may generate a direct voltage signal to be output to an external circuit 5, and the external circuit 5 is connected to the both ends of the RF/microwave energy conversion element 6, respectively, and is a device for harvesting a direct voltage signal, such as a storage battery and the like, or a transformer, thereby producing a function of power supply. Since the kinds of the external circuit 5 is not unique, and may be changed according to actual practice, which is not particularly defined here.

The first magnetic layer 2 of the fixed in-plane magnetization axis indicates that a magnetization (magnetic moment) orientation of the magnetic layer is along a direction of a film plane, and the word “fixed” indicates the direction of magnetic moment not to be easily changed.

The magnetic moment orientation of the energy conversion layer 4 is determined with respect to the direction of the film plane of the first magnetic layer 2 and includes out-of-plane orientation due to oblique to the film plane of the first magnetic layer 2, in-plane orientation due to being parallel to the film plane of the first magnetic layer 2 and out-of-plane orientation due to being perpendicular to the film plane of the first magnetic layer 2, wherein the out-of-plane orientation indicates an angle between the magnetic moment of the energy conversion layer 4 and the film plane of the first magnetic layer 2 to be larger than zero; and the in-plane orientation indicates an angle between the magnetic moment of the energy conversion layer 4 and the film plane of the first magnetic layer 2 to be equal to zero.

For the magnetic thin film, there are several factors to determine its intrinsic magnetic moment orientation: shape anisotropic field, magnetocrystalline anisotropic field, demagnetization field and stray field. Generally, there are two common situations where the orientation is lying in the film plane or perpendicular to the thin film. Recent work finds that the amplitude and direction of the magnetocrystalline anisotropic field may be effectively controlled by adjusting the film thickness and interface characteristics between the magnetic thin films, thereby resulting in the magnetic moment orientation oblique to the film plane. This state is cone-shaped mentioned in the present patent. More specific, in the cone state, the amplitude of the first-order magnetocrystalline anisotropic field is proximity to the amplitude of the demagnetization field while their directions are opposite. In this case, the effective saturation magnetization amplitude of the magnetic thin film is reduced, and the second-order magnetocrystalline anisotropic field plays a dominant role. This cone state (that is, the canted magnetic moment orientation) has the following advantages: first, low critical current density required for procession of magnetic moment; second, easy realization of the large-amplitude out-of-plane procession. These advantages make such a magnetic structure be used as the energy conversion layer with high energy conversion efficiency under low-power RF/microwave energy.

The RF/microwave signal receiving element 1 mainly includes an antenna, a RF/microwave conduction element connected with the antenna and an impedance matcher connected with the RF/microwave conduction element. The impedance matcher is connected with the first magnetic layer 2 of the RF/microwave energy conversion element 6, and the specific definition is not made here.

According to the present disclosure, large-amplitude procession of the magnetic moment in the energy conversion layer 4 of the RF/microwave energy conversion element 6 is induced by collecting external RF/microwave signal with the RF/microwave signal receiving element 1. Since the magnetic multi-layer film structure has a giant magnetoresistance effect, positive and negative charges are accumulated at both of upper and lower ends of the RF/microwave energy conversion element 6 and the accumulated positive and negative charges are output to the external circuit 5 to implement the conversion of the RF/microwave signal into a direct voltage signal.

The range of the frequency of the RF/microwave signal receiving element 1 received is 0.1 MHz-10 GHz.

The first magnetic layer 2 according to the present disclosure is a pinned magnetic layer which is constituted by at least one magnetic thin film. Amplitude of a coercive field of the magnetic thin film is 5 mT-1500 mT. The space layer 3 is made of a metal or an insulating material. The space layer 3 may be made of a metal material, such as one of copper (Cu) and silver (Ag), and a thickness thereof is 0.5 nm-5 nm. Alternatively, the space layer 3 may be made of an insulating material, such as one of magnesium oxide (MgO) and aluminum oxide, and a thickness thereof is 0.5 nm-3 nm. The energy conversion layer 4 is made of a magnetic material, such as at least one of NiFe, Fe, Co, FeB, CoFeB, Co/Pt, Co/Pd, Co/Ni, CoFeSiB and TeFeCoAl, wherein Co/Pt, Co/Pd and Co/Ni are laminated materials and the rest are all alloy materials.

The above structure has the following advantages: a magnetic tunnel junction multilayer film composed of MgO single-crystal barrier layer has a comparatively giant tunneling magnetoresistance effect and may improve energy conversion efficiency; and the energy conversion layer 4 having a canted magnetic moment orientation may implement high energy conversion efficiency under low-power RF/microwave energy.

As illustrated in FIG. 2, in the first embodiment, a laminated structure of the RF/microwave energy conversion element 6 is as follows: the space layer 3 is provided on the first magnetic layer 2, and the energy conversion layer 4 is provided on the space layer 3. A magnetization direction of the energy conversion layer 4 is perpendicular to the magnetization direction of the first magnetic layer 2, and an angle between magnetization directions of the energy conversion layer 4 and the first magnetic layer 2 is equal to 90 degrees in the absence of an external magnetic field.

As illustrated in FIG. 3, in the second Embodiment, a laminated structure of the RF/microwave energy conversion element 6 is as follows: the space layer 3 is provided on the first magnetic layer 2, and the energy conversion layer 4 is provided on the space layer 3. A magnetization direction of the energy conversion layer 4 is oblique to the magnetization direction of the thin film of the first magnetic layer 2, and the magnetization directions of the energy conversion layer 4 are oblique to the film plane of first magnetic layer 2 in the absence of an external magnetic field.

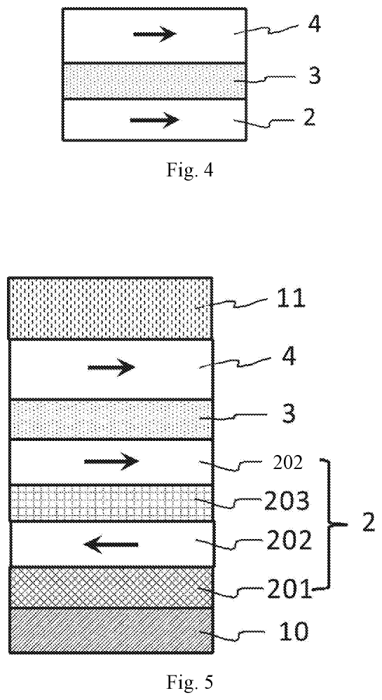

As illustrated in FIG. 4, in the third embodiment, a laminated structure of the RF/microwave energy conversion element 6 is as follows: the space layer 3 is provided on the first magnetic layer 2, and the energy conversion layer 4 is provided on the space layer 3. The magnetization direction of the energy conversion layer 4 is parallel to the film plane of the first magnetic layer 2, and the magnetization directions of the energy conversion layer 4 and the first magnetic layer 2 are parallel to the film plane of first magnetic layer 2 in the absence of an external magnetic field.

As illustrated in FIG. 5, in the fourth embodiment, a laminated structure of the RF/microwave energy conversion element 6 is as follows: the space layer 3 is provided on the first magnetic layer 2, and the energy conversion layer 4 is provided on the space layer 3, wherein the first magnetic layer 2 is constituted by laminating multilayer thin films. The first magnetic layer 2 includes an anti-ferromagnetic layer 201, two second magnetic layers 202 provided on the anti-ferromagnetic layer 201 and a metal layer 203 provided between the two adjacent second magnetic layers 202. The space layer 3 is provided on the uppermost one of the second magnetic layers 202, and the energy conversion layer 4 is provided on the space layer 3.

In the present embodiment, the magnetic moment directions of the two second magnetic layers 202 are parallel to an in-plane, that is, parallel to the film plane of the second magnetic layer 202, but the magnetic moment directions of the two second magnetic layers 202 are opposite. The magnetic moment direction of the energy conversion layer 4 is parallel to and opposite to the magnetic moment direction the uppermost one of the second magnetic layers 202.

In the fourth Embodiment, a metal buffer layer 10 may be disposed on a lower end of the first magnetic layer 2 and a metal cap 11 is disposed on the energy conversion layer 4.

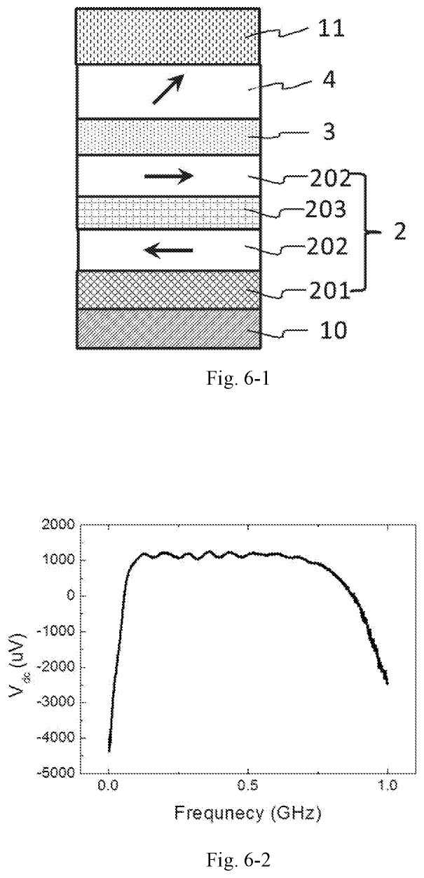

As illustrated in FIG. 6A, the fifth embodiment is different from the fourth embodiment only in that the magnetic moment direction of the energy conversion layer 4 is oblique to the magnetic moment direction of the uppermost one of the second magnetic layers 202, that is, oblique to the film plane of the second magnetic layer 202.

As an optimal solution of the present disclosure, the structure of the RF/microwave energy conversion element includes a magnetic layer 2 which has a fixed in-plane magnetization axis and is composed of four magnetic thin films PtMn with a film thickness of 15 nm, Co₇₀Fe₃₀ with a film thickness of 2.3 nm, Ru with a film thickness of 0.85 nm and Co₄₀Fe₄₀B₂₀ with a film thickness of 2.4 nm, a non-magnetic layer 3 including magnesium oxide (MgO) with a film thickness of 0.8 nm, and an energy conversion layer 4 including Co₂₀Fe₆₀B₂₀ having an canted magnetic moment orientation with a thickness of 1.53 nm, wherein PtMn, CoFe and CoFeB are all alloy materials, wherein subscripts of Co₇₀Fe₃₀, Co₄₀Fe₄₀B₂₀ and Co₂₀Fe₆₀B₂₀ refers to mass ratios of the alloy materials. The cross section of the RF/microwave energy conversion element has an ellipse shape with a long axis of 150 nm and a short axis of 60 nm. A performance test result according to the optimal embodiment is shown in FIG. 6B. In a frequency range of the RF/microwave of 0.1 MHz-1 GHz, a RF/microwave signal has a power of 32 μW. That is, it is observed that stable direct current converted energy is output within a very wide frequency range.

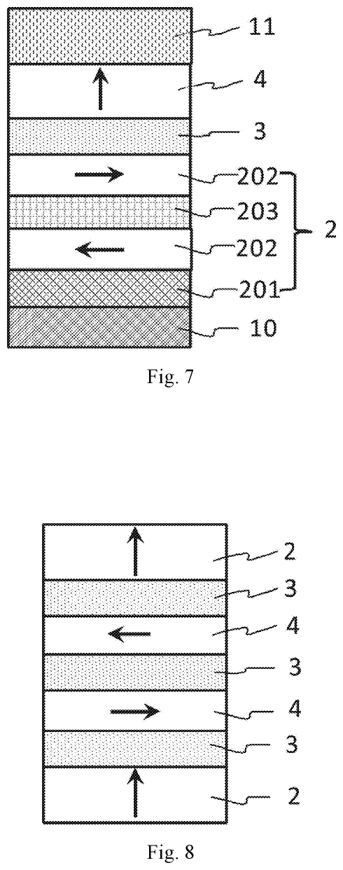

As illustrated in FIG. 7, the sixth embodiment is different from the fourth embodiment only in that the magnetic moment direction of the energy conversion layer 4 is perpendicular to the magnetic moment direction of the uppermost one of the second magnetic layers 202, that is, perpendicular to the film plane of the second magnetic layer 202.

As illustrated in FIG. 8, in the seventh embodiment, there are two first magnetic layers 2 and two energy conversion layer 4 in the RF/microwave energy conversion element 6. The energy conversion layer 4 is provided between the two first magnetic layers 2. There is a space layer 3 between the first magnetic layers 2 and the energy conversion layers 4, and there is another space layer 3 between the two adjacent energy conversion layers 4.

In the present embodiment, the magnetic moment direction of the first magnetic layer 2 is perpendicular to in-plane, that is, perpendicular to the film plane thereof. The magnetic moment directions of the energy conversion layers 4 are both parallel to in-plane, that is, parallel to the film plane of the first magnetic layer 2, and opposing to each other.

In the above the fourth embodiment to the seventh embodiment, the second magnetic layer 202 has a magnetic film structure, particularly, the second magnetic layer 202 is made of a ferromagnetic material; and the metal layer 203 is made of ruthenium or copper; and the anti-ferromagnetic layer 201 is made of IrMn or PtMn.

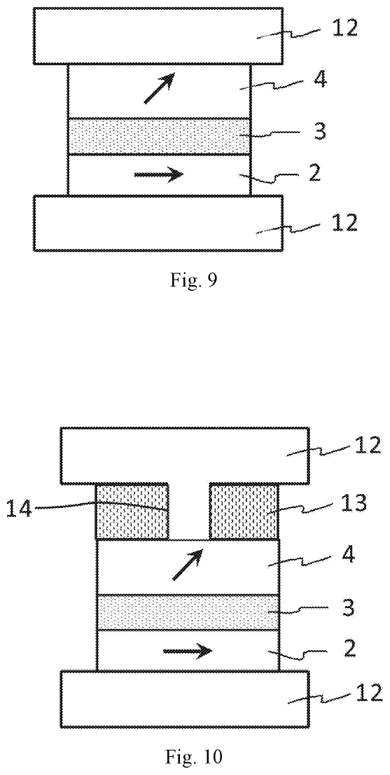

As illustrated in FIG. 9, the eighth embodiment differs from the first to third embodiments in that a metal electrode 12 may be further provided on the first magnetic layer 2 and the energy conversion layer 4, respectively. Here, the RF/microwave energy conversion element 6 has a columnar structure with a lateral size ranging from 50 nm to 500 nm by etching. The magnetoresistance effect of the RF/microwave energy conversion element 6 is comparatively strong due to such a columnar structure so as to be helpful to improve the RF/microwave energy conversion efficiency.

As illustrated in FIG. 10, the ninth embodiment differs from the eighth embodiment in that: an insulating dielectric layer 13 is disposed on the energy conversion layer 4, and the uppermost one of the metal electrodes 12 is electrically connected to the energy conversion layer 4 through at least one nano-hole 14 formed by etching the insulating dielectric layer 13, and thus a nano-point contact structure is formed. In the present embodiment, only one nano-hole 14 is provided, and an aperture of the nano-hole 14 is 30 nm-300 nm. Although the magnetoresistance effect of the ninth embodiment is weaker than that of the eighth embodiment with the columnar structure, due to such a nano-point contact structure, the ninth embodiment easily implements synchronization of a RF/microwave signal and is also helpful to improve the microwave energy conversion efficiency.

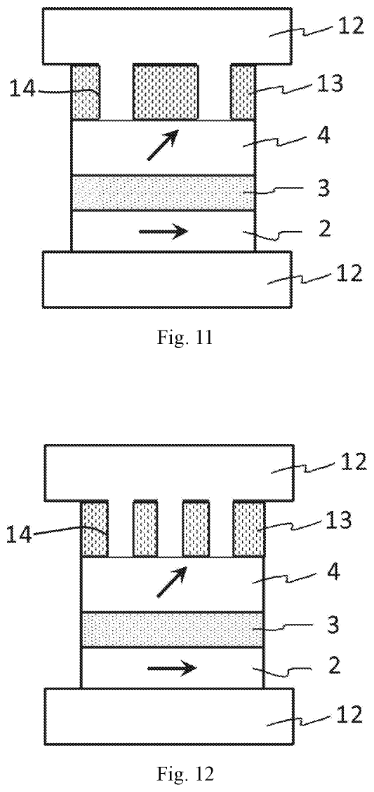

As illustrated in FIG. 11, the tenth embodiment differs from the ninth embodiment mainly in that two nano-holes 14 are provided and a distance between the two nano-holes 14 is 50 nm-2000 nm.

As illustrated in FIG. 12, the eleventh embodiment differs from the ninth embodiment mainly in that three nano-holes 14 are provided and a distance between adjacent two one of the nano-holes 14 is 50 nm-2000 nm.

The RF/microwave energy conversion element 6 according to the present disclosure may generate direct voltage signals at both ends thereof. As a broadband RF/microwave energy harvesting device, The RF/microwave energy conversion element 6 according to the present disclosure can collect RF/microwave energy from the external space and convert the RF/microwave energy into direct voltage signals. The frequency range of the collected energy is relatively wide, that is, more RF/microwave energy may be harvested and converted. Conversion efficiency is defined as: Output DC power divided by Input RF/microwave power.

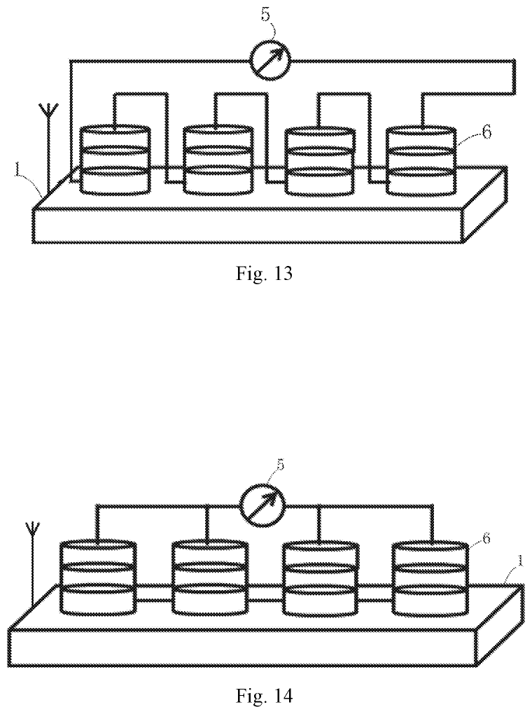

As illustrated in FIG. 13, as an optimal embodiment according to the present disclosure, four RF/microwave energy conversion elements 6 are provided, and four RF/microwave energy conversion elements 6 are connected to the external circuit 5 in series. As illustrated in FIG. 14, the RF/microwave energy conversion elements 6 are connected to each other in parallel, which can harvest RF/microwave signals having higher energy.

After being connected in series or parallel in the present disclosure, a plurality of RF/microwave energy conversion elements 6 are encapsulated as a modular assembly.

A power generation method of the broadband RF/microwave energy harvesting device according to the present disclosure includes:

RF/microwave signal is received through a RF/microwave conduction element and an impedance matching element of the external RF/microwave signal receiving element 1 and transmitted to the RF/microwave energy receiving element 6;

After the RF/microwave energy conversion element 6 has received the RF/microwave signal, the RF/microwave signal makes the magnetic moment of the energy conversion layer 4 in the RF/microwave energy conversion element 6 be rotated;

The magnetic moment is rotated such that positive and negative charges be accumulated on the upper and lower ends of the RF/microwave energy conversion element 6; and

The accumulated positive and negative charges are output to the external circuit 5 to implement the conversion of the RF/microwave energy into a direct voltage signal.

The broadband RF/microwave energy harvesting device according to the present disclosure may be used to harvesting microwave energy which will be stored through an energy storage device such as a mobile power source, and a wireless charging device may be formed by combining the RF/microwave energy harvesting device according to the present disclosure with a wireless charging coil, which may be wirelessly connected with a mobile phone, thereby solving the charging problem of the mobile phone .

The broadband RF/microwave energy harvesting device according to the present disclosure can harvest RF/microwave energy of different frequency bands from the external space. The broadband RF/microwave energy harvesting device according to the present disclosure can be applied to the wireless charging field, which is the greatest advantage thereof. Specifically, for example, the broadband RF/microwave energy harvesting device according to the present disclosure can be integrated with a chip in a mobile phone, to wirelessly charging by converting energy of WiFi wireless signal.

The broadband RF/microwave energy harvesting device according to the present disclosure, which is a nano power generation device, is suitable for various application.

By aiming at improving defects of complicated circuit structure, large size, narrow capturable frequency range, short transmission distance and the like in the general wireless charging technologies and electromagnetic energy harvesting technologies, the present disclosure provides a nano power generation device which converts electromagnetic energy into electric energy under a relatively wide frequency range (0.1 MHz-10GHz). The nano power generation device has advantages such as small size (i.e., in nanometer, much smaller than a semiconductor-based energy conversion structure), wide operating frequency range, high energy conversion efficiency per unit area, long transmission distance and so on.

Although the present disclosure is described and illustrated with reference to the specific embodiments, those skilled in the art will understand: various changes in form and details may be made therein without departing from the spirit and scope of the invention as defined by the appended claims and its equivalents.

What is claimed is:

1. A new RF/microwave energy harvesting device based on spintronics, comprising:
at least one RF/microwave energy conversion element,
wherein the RF/microwave energy conversion element comprises:
a first magnetic layer connected to a RF/microwave signal receiving element;
a non-magnetic space layer; and
an energy conversion layer accumulating positive and negative charges at both of upper and lower ends of the RF/microwave energy conversion element to implement a conversion of a RF/microwave energy into a direct voltage signal.

2. The new RF/microwave energy harvesting device based on spintronics of claim 1, wherein
the space layer is provided on the first magnetic layer, and the energy conversion layer is provided on the space layer.

3. The new RF/microwave energy harvesting device based on spintronics of claim 2, wherein the first magnetic layer comprises:
an anti-ferromagnetic layer;
at least two second magnetic layers provided on the anti-ferromagnetic layer; and
a metal layer provided between two adjacent ones of the second magnetic layers.

4. The new RF/microwave energy harvesting device based on spintronics of claim 1, wherein
the first magnetic layer includes at least two first magnetic layers, the energy conversion layer is provided between two adjacent ones of the first magnetic layers, and the space layer is provided between the first magnetic layers and the energy conversion layer.

5. The new RF/microwave energy harvesting device based on spintronics of claim 4, wherein
the energy conversion layer includes at least two energy conversion layers, and the space layer is provided between two adjacent ones of the energy conversion layers.

6. The new RF/microwave energy harvesting device based on spintronics of claim 1, wherein
the space layer is made of a metal or an insulating material.

7. The new RF/microwave energy harvesting device based on spintronics of claim 6, wherein
when the space layer is made of a metal material, the metal material is one of copper and silver; and
when the space layer is made of an insulating material, the insulating material is one of magnesium oxide and aluminum oxide.

8. The new RF/microwave energy harvesting device based on spintronics of claim 7, wherein
when the space layer is made of the metal material, the space layer has a thickness of 0.5 nm-5 nm; and
when the space layer is made of the insulating material, the space layer has a thickness of 0.5 nm-3 nm.

9. The new RF/microwave energy harvesting device based on spintronics of claim 1, wherein
the energy conversion layer is made of a magnetic material which is at least one of NiFe, Fe, Co, FeB, CoFeB, Co/Pt, Co/Pd, Co/Ni, CoFeSiB and TeFeCoAl.

10. The new RF/microwave energy harvesting device based on spintronics of claim 1, wherein
the RF/microwave energy conversion element includes two or more RF/microwave energy conversion elements, and the RF/microwave energy conversion elements are connected to each other in series or in parallel.
